(19) United States
(12) Patent Application Publication
(10) Pub. No.: US 2010/0120242 A1
(43) Pub. Date: May 13, 2010

(54) METHOD TO PREVENT LOCALIZED ELECTRICAL OPEN CU LEADS IN VLSI CU INTERCONNECTS

(75) Inventors: Sopa Chevacharoenkul, Richardson, TX (US); Phillip Daniel Matz, Allentown, PA (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/266,596

(22) Filed: Nov. 7, 2008

(51) Int. Cl. H01L 21/4763; H01L 21/44

(52) U.S. Cl. 438/633; 438/687; 257/E21.583

(57) ABSTRACT

One embodiment of the present invention relates a method for preventing the formation of electrical opens due to localized copper dissolution during fabrication of metal interconnect wires. More particularly, a semiconductor body comprising one or more exposed copper metal levels is coated with a benzotriazole (BTA) solution. The semiconductor body is then dried, resulting in a protective layer of BTA coating the copper metal levels. The protective layer of BTA passivates the exposed copper surface by forming a protective BTA layer that prevents the copper metal level from coming into direct contact with deionized water thereby preventing copper metal dissolution and providing improved integrated chip yields and reliability.

### FIELD OF INVENTION

The present invention relates generally to semiconductor device fabrication and more particularly to a method of preventing localized dissolution of copper metal interconnect levels which can cause electrical opens.

### BACKGROUND OF THE INVENTION

Modern day integrated chips are formed from millions of active semiconductor devices that are connected together by multi-level interconnection structures which couple the semiconductor devices to the outside world. In recent years, the manufacturing advances have allowed the minimum feature size of the metal interconnect structures to significantly decrease thereby increasing chip density and performance.

One such advance is the use of copper metal for device interconnect levels. Copper metal is extremely attractive as an interconnect metal because it comprises a low resistivity and a high electromigration resistance. The low resistivity of copper allows copper wires to be formed with a small cross sectional area while maintaining an acceptable RC delay constant. Furthermore, the electromigration of copper is approximately 0.01 that of aluminum at a given temperature.

Formation of metal interconnect wires is performed by forming alternating layers of metal and dielectric material on a semiconductor substrate by a variety of processes. Using a Dual Damascene process, fabrication of the metal and via levels comprises forming a metal and via level within a deposited inter-level dielectric (ILD) material layer (e.g., silicon oxide, fluorinated silicon oxide, polymers including polyimide and fluorinated polyimide, ceramics, carbon and other dielectric materials). During processing, the ILD layer is deposited and then holes (i.e., via holes) are patterned using known techniques such as the use of a photoresist material which is exposed to define a pattern. After developing, the photoresist acts as a mask through which the pattern of the ILD material is removed by a subtractive etch process (e.g., such as plasma etching or reactive ion etching) to partially form the via holes. A second patterning process proceeds to pattern metal wires. The pattern is also removed through a subtractive etch process which forms metal trenches and completes via hole etching such that the via holes extend from one surface of the ILD layer to the other surface of the ILD layer, while the metal trenches are comprised within the upper part of the ILD layer. The via holes and metal trenches are then filled a single metal deposition step to form both a via level and an abutting metal layer (e.g., the metal layer above the via). Metal may be deposited using a filling technique such as electroplating, electroless plating, chemical vapor deposition, physical vapor deposition or a combination of methods.

After metal deposition, a means is used to remove excess amounts of the deposited layers and to ensure that local and global planarity of the surface in preparation prior to application of the next layer. Planarity is extremely important in multilevel metal interconnects, because lithographic focus constraints require that the substrate surface be planar on both a global and a local scale. If the surface is not planar, the exposure tool may not be able to focus properly thereby causing out of focus images (e.g., out of focus metal interconnect exposure) and poor image quality. Such problems provide enormous barriers to successful fabrication of integrated chips for technology nodes currently in production.

Chemical mechanical polishing (CMP) has emerged as a promising planarization technology since it can potentially reduce the process complexity and achieve global planarization. Typically, chemical mechanical polishing is performed by a CMP tool comprising a rotating pad. A wafer is loaded into the CMP tool by an automated mechanized arm. The wafer is mounted upside down in a carrier on a backing film and is held with a fixed downward force against a rotating polishing pad. Mechanical grinding alone causes too much surface damage, while wet etching alone cannot attain good planarization, and therefore an aqueous polishing slurry (slurry) comprising various chemicals and suspended abrasive particles (e.g., silica or alumina) is continuously provided between the wafer and the rotating polishing pad. The combination polishing slurry provides both mechanical and abrasive polishing effects. A combination of the abrasive particles, applied force, imposed relative velocity, and the chemical reaction between the material being polished and constituents in the solution result in an enhanced polishing rate.

### SUMMARY OF THE INVENTION

The following presents a simplified summary in order to provide a basic understanding of one or more aspects of the invention. This summary presents one or more concepts of the invention in a simplified form as a prelude to the more detailed description that is presented later and is not an extensive overview of the invention. In this regard, the summary is not intended to identify key or critical elements of the invention, nor does the summary delineate the scope of the invention.

One embodiment of the present invention relates a method for preventing the formation of electrical opens due to localized copper dissolution during fabrication of metal interconnect wires. More particularly, a semiconductor body comprising one or more exposed copper metal levels is coated with a benzotriazole (BTA) solution. The semiconductor body is then dried, resulting in a protective layer of BTA coating the copper metal levels. The protective layer of BTA prevents the copper metal levels from coming into direct contact with degenerative elements such as deionized water and therefore prevents the dissolution of copper metal resulting in improved integrated chip yields and reliability.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIGS. 1A-1C illustrate how copper dissolution forms opens in copper metal interconnects;

FIG. 2 illustrates a method for preventing copper dissolution during metal level fabrication of an integrated chip; and

FIGS. 3-8 illustrate cross sectional views of the method of FIG. 2.

### DETAILED DESCRIPTION OF THE INVENTION

The present invention will now be described with reference to the attached drawing figures, wherein like reference numerals are used to refer to like elements throughout, and wherein the illustrated structures and devices are not necessarily drawn to scale.

Modern integrated chips are formed by extremely complicated processes involving a large number of steps. In particular, during the formation of metal interconnect wires a diffusion barrier (e.g., Tantalum) and a copper seed layer are deposited (e.g., by physical vapor deposition) onto a patterned inter-level dielectric material (ILD material), to be followed by depositing copper metal to form interconnect layers (e.g., by electrochemical deposition). The metal deposition results in excess deposited metal forming an uneven surface. Therefore, after metal deposition the chip is moved to another processing location where it undergoes chemical mechanical polishing (CMP) to remove excess amounts of the deposited metal and to ensure that local and global planarity of the surface in preparation prior to application of the next layer. In the time between the metal deposition (e.g., copper deposition) and the CMP, the copper metal is susceptible to damage such as copper dissolution (i.e., in regions where the copper metal level comes into contact with deionized water the copper metal will dissolve removing the copper interconnect and thereby causing electrical opens in the interconnect wires). Such damage can result in low integrated chip failure or reliability problems.

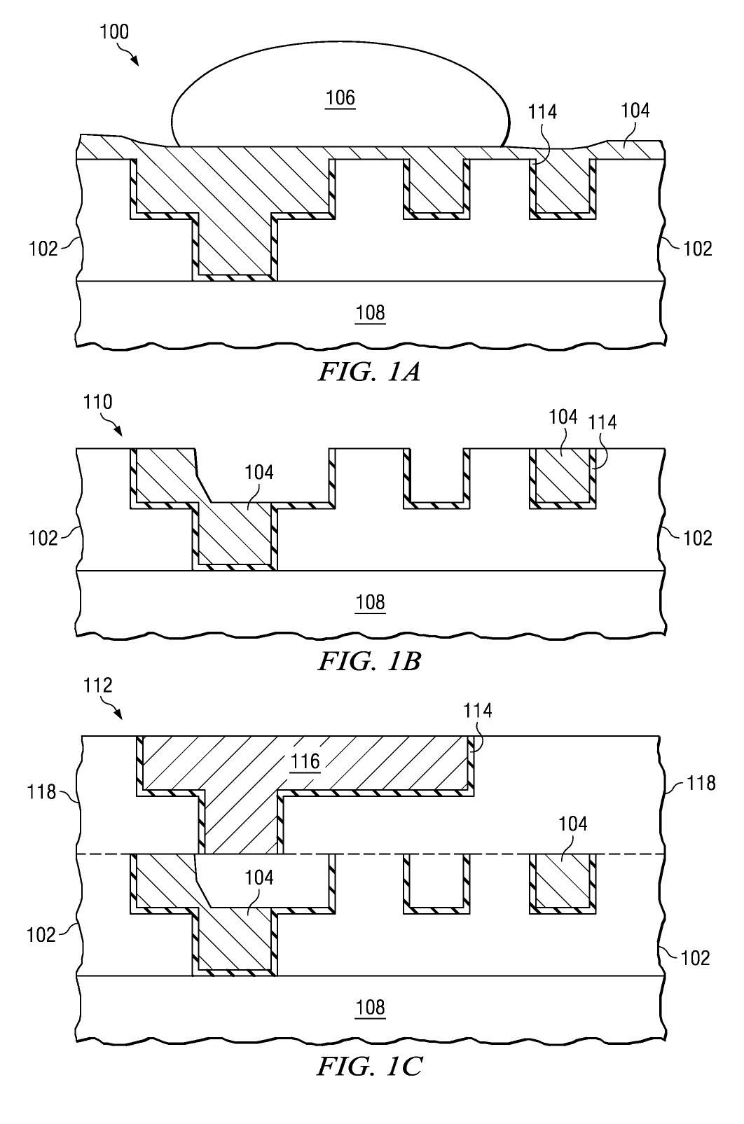

FIGS. 1A-1C schematically illustrate a cross-sectional view of a semiconductor structure at different stages of a dual damascene metal formation process. In particular, FIGS. 1A-1C, illustrate the effect of copper dissolution on metal interconnect wires.

FIG. 1A shows a cross-sectional view 100 of the semiconductor body 108 comprising a copper metal 104 level that has been deposited onto an ILD level 102. The copper metal is separated from the ILD level by a diffusion barrier layer 114. As illustrated in FIG. 1A a water droplet 106 is in contact with a part of the copper metal 104.

FIG. 1B shows a cross-sectional view 110 of the semiconductor body 108 at a later time wherein localized copper dissolution has occurred. At the later time, copper metal 104 that was in contact with the water droplet 106 has been dissolved leaving a depression (void) in the copper metal 104 such that the copper metal does not extend to the top of the ILD level 102.

FIG. 1C illustrates a cross sectional view 112 of the semiconductor body 108 at a downstream processing step wherein an additional inter-level dielectric layer 118, and metal level 116 (e.g., comprising a via level and a metal level) have been formed on top of ILD level 102 and copper metal level 104. As illustrated in FIG. 1C, dissolution of the copper metal level 104 has formed an open on the electrical net between copper metal level 104 and metal level 116 (e.g., inter-level dielectric layer 118 electrically separates metal level 116 from copper metal level 104 thereby causing an open in the circuit). Therefore, during integrated chip fabrication copper dissolution, as illustrated in FIGS. 1A-1C, can form opens in copper interconnect wires which will result in low yields and reliability. Accordingly, there is a need for a method to prevent copper metal interconnect wire opens caused by exposure of copper metal to water.

A first embodiment of the present invention relates a method for preventing formation of electrical opens due to localized copper dissolution during fabrication of metal interconnect wires. More particularly, a semiconductor body (e.g., silicon wafer) having an exposed copper surface is coated with a benzotriazole solution (BTA solution). The semiconductor body is then dried, resulting in a protective layer of BTA coating the copper metal surface. The protective layer of BTA passivates the exposed copper surface by preventing the copper metal from coming into direct contact with a degenerative element such as deionized water. The BTA treatment therefore makes the copper metal unreactive to degenerative elements, thereby preventing dissolution of copper metal and resulting in improved integrated chip yield and reliability.

In one embodiment the copper metal surface is comprised of one or more copper metal levels formed during back end of the line metallization of an integrated chip. In such an embodiment, the BTA coating is deposited down stream from deposition of copper metal (e.g., deposition of copper by chemical vapor deposition), for example.

The BTA solution can be deposited onto the copper metal regions of a semiconductor body according to various of embodiments. For example, in one embodiment a semiconductor body having an exposed copper surface is immersed into a BTA solution to form a protective layer of BTA that protects the copper (e.g., copper metal lines). In such an embodiment, a BTA solution is held at a desired temperature. The semiconductor body (e.g., silicon wafer) is dipped into the BTA solution for an amount of time sufficient to form a BTA layer on the surface of the semiconductor body.

In one particular example, a plurality of silicon wafers (e.g., 200 mm wafers) comprising a plurality of semiconductor devices are loaded into a wafer cassette. An automated mechanized arm is configured pick up the wafer cassette and dip it into the BTA solution comprised within a processing station (e.g., a wet bench). The wafer cassette is submerged into the solution for a specified time and then is removed and transferred to another processing station (e.g., wet bench) where the wafers are dried prior to additional processing (e.g., chemical mechanical polishing).

In an alternative embodiment, the BTA solution is deposited by spinning the BTA solution onto the semiconductor body (e.g., silicon wafer). In such an embodiment, BTA solution is deposited onto a semiconductor body and then the semiconductor body is spun at a high rate of RPMs (e.g., 2000 RPM) to form a substantially uniform layer of BTA solution on the surface of the semiconductor body.

As provided herein, the BTA solution can comprise a number of forms. In one embodiment the BTA solution is comprised within a water solvent to form an aqueous based BTA solution. In an alternative embodiment, the BTA solution is added to an alcohol based solution. In either embodiment, the BTA solution may comprise various concentrations of BTA along with various additives.

The concentration of the BTA solution within a solution may vary. In one embodiment the BTA solution is comprised of a BTA concentration that is approximately 0.01% by weight. In another embodiment, the BTA solution is comprised of a BTA concentration that is approximately 0.1% by weight. In another embodiment the BTA solution is comprised of a BTA concentration that is between 0.01% and 0.1% by weight.

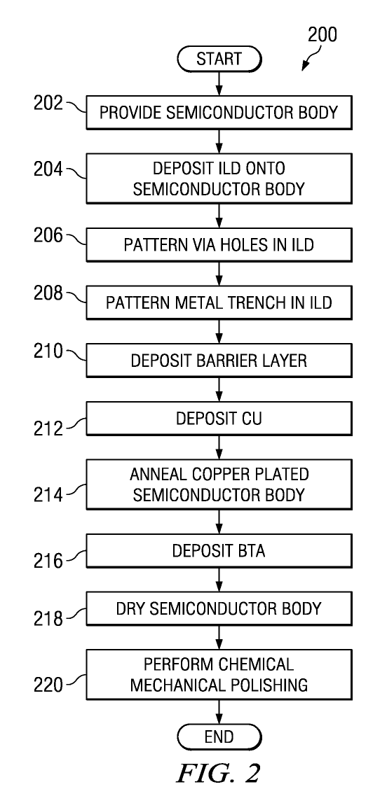

FIG. 2 illustrates a method of metal interconnect wire fabrication according to the present invention. In particular, the method of FIG. 2 includes a BTA 25 treatment of the copper metal level prior to chemical mechanical polishing (CMP). The BTA treatment forms a protective layer that separates the copper metal level from external degenerative solutions such as water. In FIG. 2, the BTA treatment is specifically placed after metal level disposition and before CMP due to the vulnerability of exposed copper metal levels at that point in an integrated chip fabrication process. However, it will be appreciated that BTA treatment of copper may be performed at alternative locations within the metal level formation.

While method 600 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Also, one or more of the acts depicted herein may be carried out in one or more separate acts and/or phases.

At 202 a semiconductor substrate is provided. The substrate may comprise any type of semiconductor body (e.g., silicon, SiGe, SOI) such as a semiconductor wafer or one or more die on a wafer, as well as any other type of semiconductor and/or epitaxial layers formed thereon and/or otherwise associated therewith.

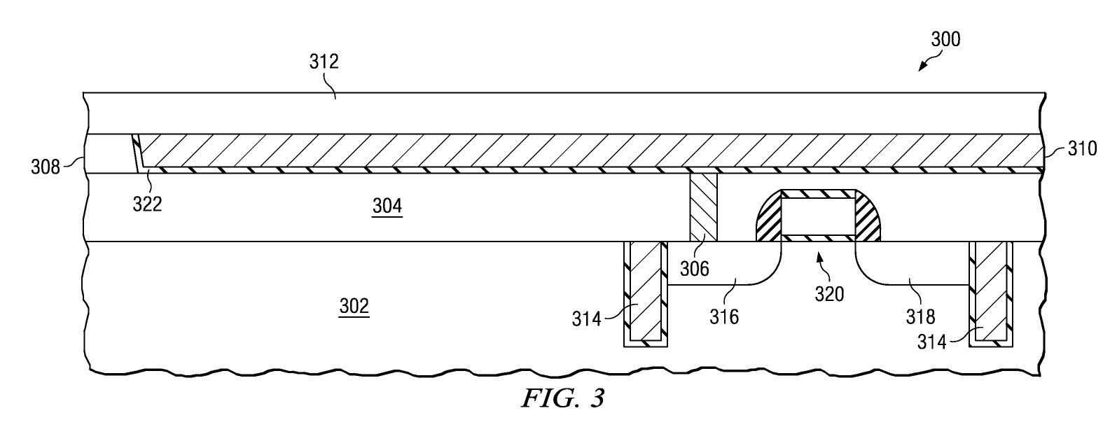

At 204 an ILD material layer is formed on the semiconductor substrate. In general, ILD layers having low dielectric constants are used for thin metal layers. In one embodiment an ultra-low dielectric material is deposited onto the semiconductor substrate. In an alternative embodiment, silicon oxycarbide (SiCO) is deposited as an ILD layer onto the semiconductor substrate. Alternative dielectric materials may also be used such as silicon oxide, fluorinated silicon oxide, polymers including polyimide and fluorinated polyimide, ceramics, carbon, etc. FIG. 3 schematically illustrates a cross sectional view 300 of one embodiment of the present invention wherein a semiconductor substrate 302 comprises an ILD layer 312 formed on the semiconductor substrate 302. As shown in FIG. 3, the ILD layer 312 is formed above a conductive metal layer 310 which is configured to connect to a semiconductor device (e.g., comprising a source 316, a drain 318, a gate 320, and STI trenches 314) by way of a contact 306. As shown in FIG. 3 the copper metal layer 310 is formed from by a single damascene process (illustrated by the formation of ILD layer 304 for contact 306 and ILD layer 308 for copper metal layer 310).

Via holes are patterned into the ILD layer at 206. Patterning of one or more via holes is performed using known techniques such as the use of a photoresist material which is exposed to define a pattern. After developing, the photoresist acts as a mask through which the pattern of the ILD material is removed by a subtractive etch process (e.g., such as plasma etching or reactive ion etching) to partially form the one or more via holes.

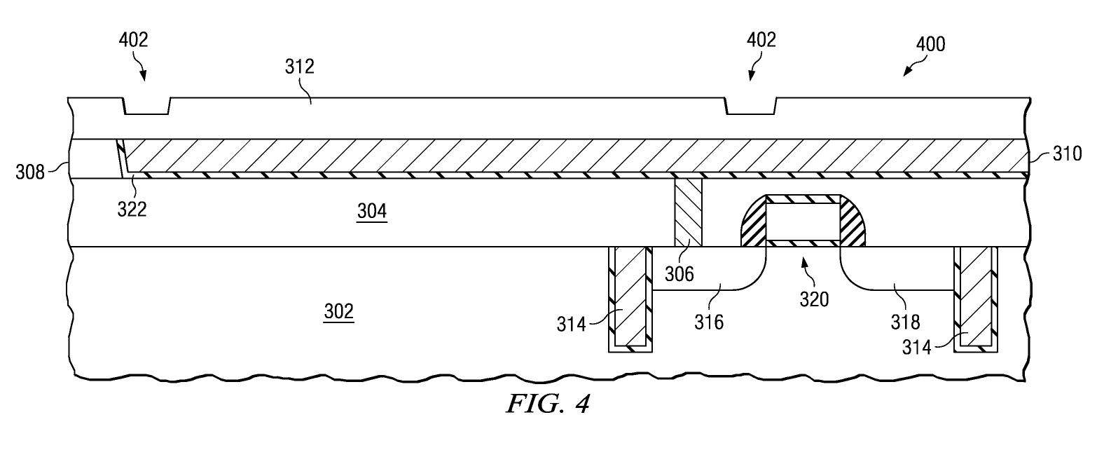

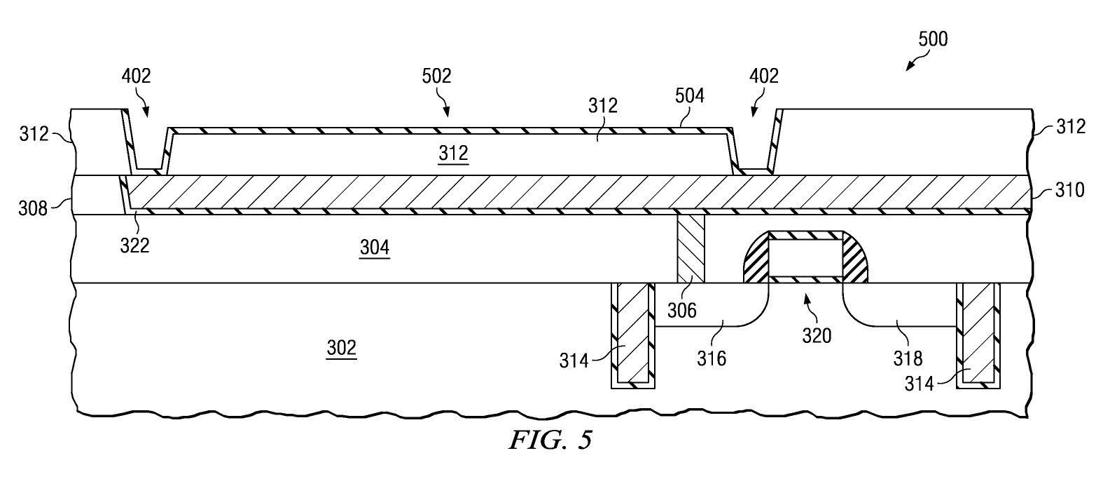

FIGS. 4-5, illustrate metal formation by a Dual Damascene process. In the Dual Damascene process fabrication of the metal and via levels comprises forming a metal and via level within a single deposited ILD layer (e.g.,312). FIG. 4 illustrates a cross sectional view 400 of one embodiment of the present invention wherein via holes 402 are formed in ILD layer 312 by means of a dual damascene process. As shown in FIG. 4, the via holes 402 are extend through the upper portion of ILD layer 312 during initial patterning.

At 208 metal trenches are patterned. One or more metal trenches are formed through a second patterning process which is used to complete the one or more via holes and pattern one or more metal trenches used in formation of metal interconnect wires. The patterned metal trenches are also removed through a subtractive etch process. FIG. 5 illustrates a cross sectional view 500 of one embodiment of the present invention wherein the one or more metal trenches 502 are formed in a dual damascene process. The one or more metal trenches 502 are formed over via holes 402 in the ILD layer 312. The one or more metal trenches 502 are formed during an etch that extends the metal trenches one or more into the upper part of ILD layer 312 while further extending the via holes 402 to through ILD layer 312.

A diffusion barrier layer is deposited onto the patterned metal trenches at 210. The diffusion barrier is deposited onto the ILD surface prior to copper deposition. A diffusion barrier layer is a thin layer that act as a barrier to prevent copper from corrupting the ILD material through diffusion. Diffusion barrier layers also offer good adhesive properties so that the copper metal adheres well to the ILD material. In one embodiment the diffusion barrier layer is comprised of Tantalum (Ta). In an alternative embodiment the diffusion barrier layer comprises tantalum nitride (TaN). It will be appreciated that a wide range of diffusion barrier layers may be used in conjunction with the method provided herein.

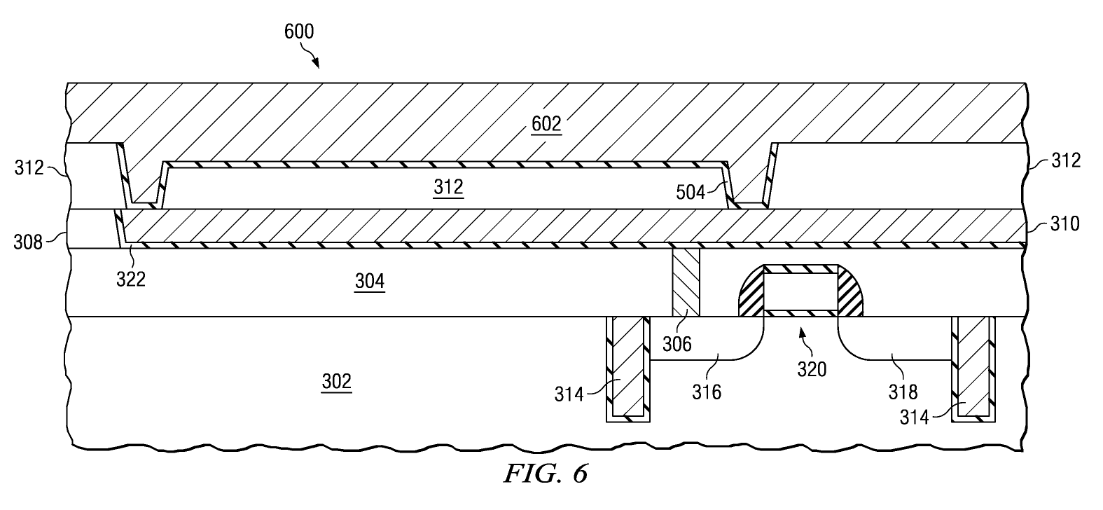

At 212 copper metal is deposited onto the patterned ILD layer. Copper metal is deposited above the barrier layer and is provided to fill the patterned ILD layer (i.e., the one or more via holes and metal trenches). Copper metal may be deposited using a filling technique such as electroplating, electroless plating, chemical vapor deposition, physical vapor deposition or a combination of methods. FIG. 6 illustrates a cross sectional view 600 of one embodiment of the present invention wherein copper metal 602 is deposited into the via holes 402 and one or more metal trenches 502 to form copper metal interconnect levels (i.e., via and wire levels). The copper metal 602 is separated from the ILD layer 312 by means of a diffusion barrier layer 504 as described in act 210. As illustrated in FIG. 6, during deposition excess copper metal is formed above the top of ILD layer 312.

In one particular embodiment a copper seed layer is deposited onto the barrier layer. The copper seed layer is deposited by chemical vapor deposition and is followed by electrochemical deposition process through which copper is formed in the patterned ILD layer (e.g., metal trenches, via holes) to a specified thickness (e.g., 150 nm for a first metal level). In a dual damascene process the via holes and metal trenches are filled in a single metal deposition step to form both a via level and an abutting metal layer (e.g., the metal layer above the via). It will be appreciated that copper metal deposition by any method (e.g., PVD, CVP, electroplating, etc.) will result in excess copper metal material on the surface of the integrated chip (e.g., above the ILD layer).

The copper plated semiconductor body is annealed at 214. The copper metal is annealed to improve the physical and electrical characteristics of the copper (e.g., reduced electromigration). In one embodiment the copper plated semiconductor body is annealed in a high temperature furnace at a temperature of 200° C. in N₂ for 30 minutes.

At 216 a BTA solution is deposited onto the semiconductor body. The BTA can be deposited onto the semiconductor body by immersion of the semiconductor body into a BTA bath or by spinning the BTA solution onto the surface of the semiconductor body as described above. The BTA solution will particularly be deposited onto exposed surfaces of the deposited copper metal.

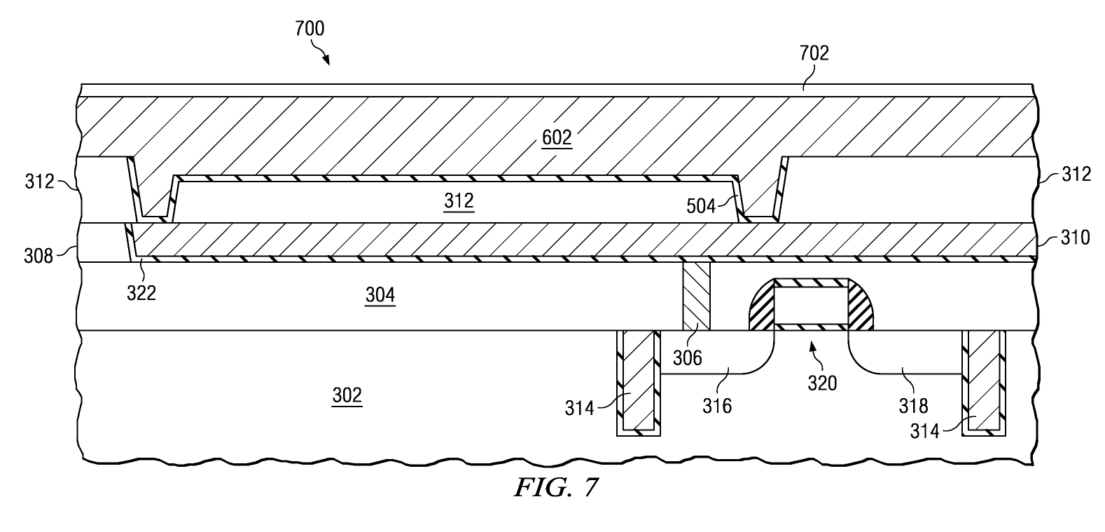

At 218 the BTA solution is allowed to dry onto the semiconductor body. When the BTA solution is dried it forms a protective layer that prevents the copper from degradation. FIG. 7 illustrates a cross sectional view 700 of one embodiment of the present invention wherein a protective BTA layer 702 is formed onto the copper metal 602. As illustrated in FIG. 7 the protective BTA level 702 is formed along the entire surface of the copper metal 602 therefore preventing dissolution of the copper metal 602 by preventing direct contact of degenerative elements (e.g., deionized water) with the copper metal 602.

Drying the wafer may be performed according to various methods. For example, in one embodiment a spin dry system is used. Spin dry systems rely on centrifugal forces which result from spinning wafers at high velocities (e.g., 2,700 to 5,000 rpm) to drive water droplets radially outward from the wafer surfaces, and to thereby remove all water from the wafer surfaces. In an alternative embodiment the semiconductor body can be dried in a heated N₂/IPA cloud above water.

Chemical mechanical polishing is performed at 220. Chemical mechanical polishing planarizes the surface of the semiconductor body by removing the excess copper metal material from the surface of the semiconductor body leaving copper filled metal wire and via levels. CMP will additionally remove the protective layer of BTA from the surface of the semiconductor body.

In the method of FIG. 2, it will be appreciated that the BTA coating is applied (e.g., illustrated in act 216) and dried (e.g., illustrated in act 218) prior to performing chemical mechanical polishing (e.g., illustrated in act 220). This ordering allows for the formation of a protective BTA layer over the copper metal which is effective in preventing Cu dissolution by water droplets that come into contact with the semiconductor body during placement into or while in the chemical mechanical polishing tool.

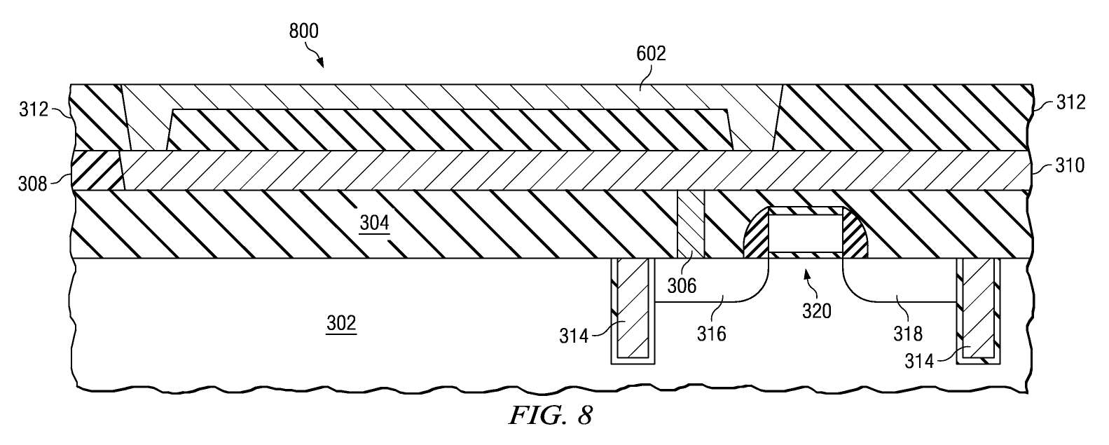

FIG. 8 illustrates a cross sectional view 800 of a copper metal level resulting from metal level formation according the method of FIG. 2. It will be noted that the resulting copper metal 602 has a planar surface and that the BTA layer has been removed, thereby leaving no BTA solution comprised within the post CMP integrated chip.

It will be appreciated that additional acts may be included into the method of FIG. 2. For example, in one embodiment after CMP is performed on the semiconductor body a dielectric copper diffusion barrier is deposited to prevent diffusion of the copper metal into the abutting ILD layers. Furthermore, additional dielectric layers or metal layers (e.g., copper metal layers, aluminum metal layers) may be formed above and/or abutting copper metal layer 602.

Furthermore, it will be appreciated that different copper metal levels (e.g., first copper metal level, second copper metal level, etc.) within a back end of the line (BEOL) metal stack may be formed by making variations in the above process. For example, in one embodiment the first metal level is formed using a single damascene process, in which case, act 206 is excluded from the method. Similarly, the last metal level may be formed according to variations on the above method. The inventors have contemplated variations in the above process as are driven by requirements of specific level processes.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of metal interconnect wire fabrication which prevents electrical opens due to localized copper dissolution, comprising:
providing a semiconductor body;
depositing a copper metal level comprising an exposed copper surface; and
depositing a benzotriazole (BTA) solution onto the deposited copper metal level, wherein the BTA solution prevents copper dissolution from the copper metal level through passivating the exposed copper surface by forming a protective layer which prevents the copper metal level from coming into direct contact with deionized water.

2. The method of claim 1, wherein the semiconductor body is dried after depositing the BTA solution.

3. The method of claim 1, further comprising performing chemical mechanical polishing (CMP) with a polishing slurry on the semiconductor body;

4. The method of claim 3, further comprising:
depositing an inter-level dielectric (ILD) material onto the semiconductor body; and
selectively patterning and etching the ILD material to form one or more metal trenches prior to performing CMP.

5. The method of claim 4, further comprising selectively patterning and etching the ILD material to form one or more via holes within the ILD material prior to forming the one or more metal trenches.

6. The method of claim 5, further comprising:
depositing a copper diffusion barrier onto the ILD material prior to depositing the copper metal level; and
annealing the semiconductor body after depositing the copper metal.

7. The method of claim 1, wherein the BTA solution comprises an aqueous based solution.

8. The method of claim 1, wherein the BTA solution comprises an alcohol based solution.

9. The method of claim 1, wherein depositing the copper metal level comprises forming a copper seed layer on the patterned ILD material and then electroplating copper to fill the one or more via holes and metal trenches.

10. The method of claim 1, wherein depositing the BTA solution comprises immersing the semiconductor body into the BTA solution.

11. The method of claim 1, wherein depositing the BTA solution comprises spinning the BTA solution onto the semiconductor body.

12. The method of claim 1, wherein the BTA solution comprises a BTA concentration between 0.01% and 0.1% by weight.

13. A method for preventing formation of electrical opens due to localized copper dissolution, comprising:
depositing a copper metal onto a semiconductor body, wherein the copper metal level comprises an exposed surface;
depositing a benzotriazole (BTA) solution onto the exposed surface of the copper metal; and
drying the BTA solution to form a protective BTA layer above the deposited copper metal, wherein the protective BTA layer passivates the exposed surface of the deposited copper metal by preventing the exposed surface from coming in contact with a degenerative element.

14. The method of claim 13, wherein the degenerative element comprises deionized water.

15. The method of claim 13, wherein the BTA solution comprises an aqueous based solution having a BTA concentration between 0.01% and 0.1% by weight.

16. The method of claim 13, wherein the BTA solution comprises an alcohol based solution having a BTA concentration between 0.01% and 0.1% by weight.

17. The method of claim 13, wherein the deposited copper metal comprises one or more metal interconnect levels formed on a semiconductor body as part of an integrated chip.

18. The method of claim 13, wherein depositing the BTA solution comprises immersing the semiconductor body into the BTA solution.

19. The method of claim 13, wherein depositing the BTA solution comprises spinning the BTA solution onto the semiconductor body.

20. A method for preventing copper dissolution during metal level fabrication of an integrated chip, comprising:
providing a semiconductor body;
depositing an inter-level dielectric (ILD) material onto the semiconductor body;
patterning the inter-level dielectric material to form one or more via holes;
patterning the inter-level dielectric material to form one or more metal trenches;
depositing a copper metal level comprising an exposed copper surface, wherein the copper metal level is formed by depositing a copper seed layer on the patterning ILD layer and then electroplating copper to fill the one or more via holes and metal trenches;
depositing an aqueous based benzotriazole (BTA) solution onto the deposited copper metal level by immersing the semiconductor body into the BTA solution, wherein the BTA solution passivates the exposed copper surface by preventing the copper metal level from coming into direct contact with deionized water thereby preventing copper dissolution;
drying the BTA solution to form a protective BTA layer on the deposited copper metal level; and
performing chemical mechanical polishing (CMP) with a polishing slurry on the semiconductor body.
